(19) United States
(12) Patent Application Publication
(10) Pub. No.: US 2023/0395445 A1
(43) Pub. Date: Dec. 7, 2023

(54) GLASS CORE ARCHITECTURES WITH DIELECTRIC BUFFER LAYER BETWEEN GLASS CORE AND METAL VIAS AND PADS

(71) Applicant: Intel Corporation, Santa Clara, CA (US)

(72) Inventors: Srinivas V. Pietambaram, Chandler, AZ (US); Kristof Darmawikarta, Chandler, AZ (US); Tarek A. Ibrahim, Mesa, AZ (US); Jeremy D. Ecton, Gilbert, AZ (US); Brandon Christian Marin, Gilbert, AZ (US); Gang Duan, Chandler, AZ (US); Suddhasattwa Nad, Chandler, AZ (US); Yi Yang, Gilbert, AZ (US); Benjamin T. Duong, Phoenix, AZ (US); Junxin Wang, Gilbert, AZ (US); Sameer R. Paital, Mesa, AZ (US)

(73) Assignee: Intel Corporation, Santa Clara, CA (US)

(21) Appl. No.: 17/833,650

(22) Filed: Jun. 6, 2022

(51) Int. Cl. H01L 23/15; H01L 23/498; H01L 21/48; H05K 1/03; H05K 3/40

(52) U.S. Cl. CPC H01L 23/15; H01L 23/49827; H01L 21/486; H05K 1/0306; H05K 3/4061

(57) ABSTRACT

In one embodiment, a substrate includes a glass core layer defining a plurality of holes between a first side of the glass core layer and a second side of the glass core layer opposite the first side and a conductive metal inside the holes of the glass core layer. The conductive metal electrically couples the first side of the glass core layer and the second side of the glass core layer. The substrate also includes a dielectric material between the conductive metal and the inside surfaces of the holes of the glass core layer.

### BACKGROUND

Continued growth in computing and mobile devices will continue to increase the demand for greater bandwidth density within and reliability of semiconductor packages.

### BRIEF DESCRIPTION OF THE DRAWINGS

FIG. 1 illustrates a cross section side view of an example glass core substrate with a plurality of plated through glass vias (TGV) that have metal pads in contact with the glass core.

FIG. 2 illustrates a cross section side view of a glass core substrate with a plurality of plated TGVs that have metal pads with a dielectric separating the metal pad from a surface of the glass core.

FIG. 3 illustrates an example package substrate with a glass core having dielectric buffer layer in accordance with embodiments herein.

FIG. 4 illustrates an example multi-die package with a glass core having a dielectric buffer layer in accordance with embodiments herein.

FIG. 5 illustrates another example multi-die package with a glass core having a dielectric buffer layer in accordance with embodiments herein.

FIG. 6 illustrates an example process for manufacturing the package substrate of FIG. 3.

FIGS. 7A-7C illustrate example processes for manufacturing the multi-die packages of FIGS. 4-5.

FIGS. 8A-8B illustrate example systems that may incorporate the glass core architectures described herein.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIG. 11 is a block diagram of an example electrical device that may include a microelectronic assembly, in accordance with any of the embodiments disclosed herein.

### DETAILED DESCRIPTION

Integrated circuit apparatuses continue to shrink in size, and with this shrinkage, improving device performance has been focused in two directions (1) to achieve chip stacking using thinned chips, and (2) increasing input/output (I/O) density in the substrate for multichip integration. Manufacturing these ever-increasing apparatuses has been made possible with a rigid carrier wafer, such as a glass-based core wafer, in a temporary bonding and debonding technology. However, one of the challenges associated with the temporary bonding and debonding technology is the warpage or shrinkage control after removal of the rigid carrier. Once the rigid glass carrier is de-bonded after bump formation, the substrate might be expected to warp due to inbuilt residual stress and CTE (coefficient of thermal efficiency) mismatch between various components, e.g., between Silicon (2.6 ppm/° C.), ABF (˜39 ppm/° C.) and Copper (17 ppm/° C.). This can impact the back-end process for bump formation and the assembly process.

One way to tackle the above problem is to use glass as a permanent substrate core. A glass core since glass is stiffer than an organic core (e.g., having a higher modulus of elasticity 60-90 GPa compared with a modulus of elasticity ˜25-30 GPa for the organic core). The permanent glass core can restrict warpage and scaling and thereby maintain the TTV requirement of 2-3 μm for ≤30 μm bump pitch scaling. However, one of the draw backs associated with glass is its fragility, and excess metallization around and within the glass core can result in excess stress and thereby result in micro cracks within the glass core.

Accordingly, in embodiments herein, integrated circuit apparatuses (e.g., package substrates) include glass core-based substrates with a dielectric buffer layer between the glass core and metal vias/pads that are in/on the glass core. The dielectric buffer layer may improve glass core reliability over systems that do not incorporate such a buffer layer, as such systems may fail due to stress cracking as described above. The buffer layer may include one or more of SiNx, SiOxNy, SiC, or a similar dielectric material that is deposited on the top and bottom of the glass core as well as in the sidewalls of drilled via holes.

Embodiments herein may provide one or more advantages over current technologies. For example, certain embodiments may provide substrates with less warpage for higher I/O density patterning (e.g., with 2/2 μm FLS and ≤30 μm FLI BP scaling). This can provide better product yield for glass core substrates, and in some cases, improved performance (e.g., improve Imax and reliability of the metal vias) over certain current techniques. As another example, the buffer layer can also act as an adhesion promotion layer for subsequent copper (or copper alloy) films that may be deposited thereon and may prevent the need for a Titanium metal layer that is deposited on the glass for the adhesion of copper films.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

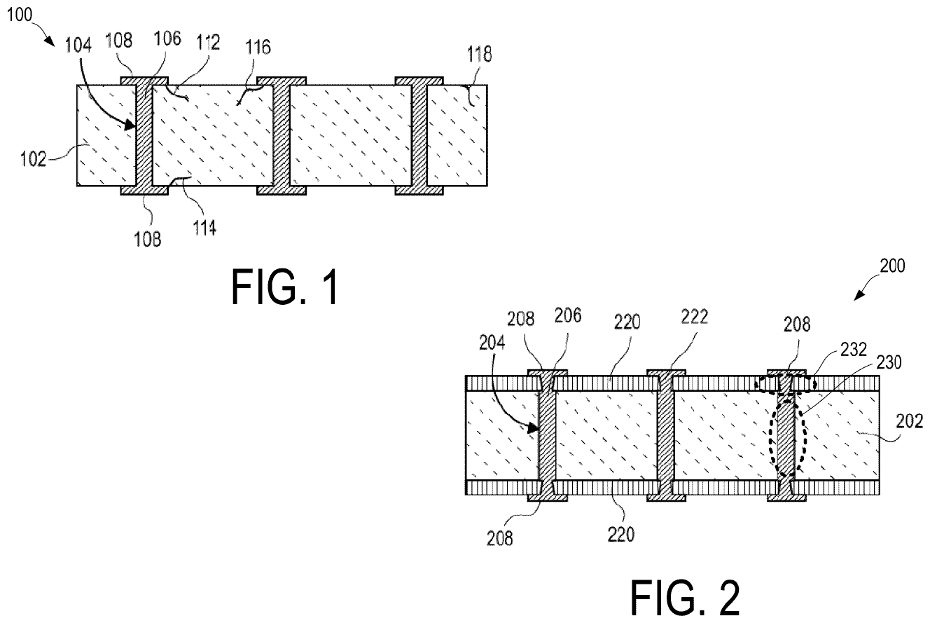

FIG. 1 illustrates a cross section side view of an example glass core substrate with a plurality of plated through glass vias (TGV) that have metal pads in contact with the glass core. The substrate 100 includes a glass core 102 with a plurality of TGV 104 extending from a top side of the glass core 102 to through a bottom side of the glass core 102. The TGV 104 may include a conductive material 106, such as copper, to electrically couple the top side and the bottom side of the glass core 102. The conductive material 106 may be completely filled within the TGV 104 or may be plated to a wall of the TGV 104.

Pads 108 may be physically and electrically coupled with the conductive material 106. As a result of the manufacturing process, the pads 108 are in physical contact with a surface of the glass core 102. Because the pads 108 and the conductive material 106 form a single metallic conductive unit, during operation they may provide stresses and strains to the surface or to the inner glass core 102, as shown by cracks 112, 114, 116, 118. These may result due to stress to the substrate 100 during the manufacturing process, and due to a CTE mismatch between the conductive material 106 and the glass core 102. This CTE mismatch may be heightened during temperature variations that occur during manufacturing, or temperature variations that occur during operation of a package into which the substrate 100 may be located.

FIG. 2 illustrates a cross section side view of a glass core substrate with a plurality of plated TGVs that have metal pads with a dielectric separating the metal pad from a surface of the glass core. Substrate 200 includes a glass core 202 with a plurality of TGV 204 extending from a top side of the glass core 202 through a bottom side of the glass core 202. The TGV 204 may include a conductive material 206, such as copper or a copper alloy, to electrically couple the top side and the bottom side of the glass core 202. The conductive material 206 may be completely filled within the TGV 204 or may be plated to a wall of the TGV 204. As shown, a layer of dielectric material 220 may be placed on a surface of the glass core 202, with cavities 222 formed within the layer of dielectric material into which conductive material such as conductive material 206 may be placed. Pads 208 may be subsequently physically and electrically coupled with the conductive material 206. As a result of this, the pads 208 are in physical contact with a surface of the layer of dielectric material 220 and are not in direct physical contact with a surface of the glass core 202.

While the dielectric material 220 may provide improvements over the example shown in FIG. 1, the TGVs 204 may still be in contact with the glass core inside the sidewalls of the TGV (e.g., in the area 230 shown). In addition, the diameter of the TGVs 204 may need to be reduced in the area 232 shown, which can cause performance issues, such as reduced Imax (maximum current handling ability), or reduced reliability/yield. Thus, aspects of the present disclosure provide an approach to address these or other issues by depositing a dielectric buffer layer (including, e.g., SiNx, SiOxNy, SiC or another suitable type of dielectric material) on the glass core surface as well as in the TGV sidewalls. In this way, metal vias will be able to have a consistent diameter throughout, overcoming certain issues seen with the reduced diameter as shown in the area 232. Metal routing (including pads, traces, planes, etc.) can be done on top of the buffer layer, which can also address stress-induced issues as well.

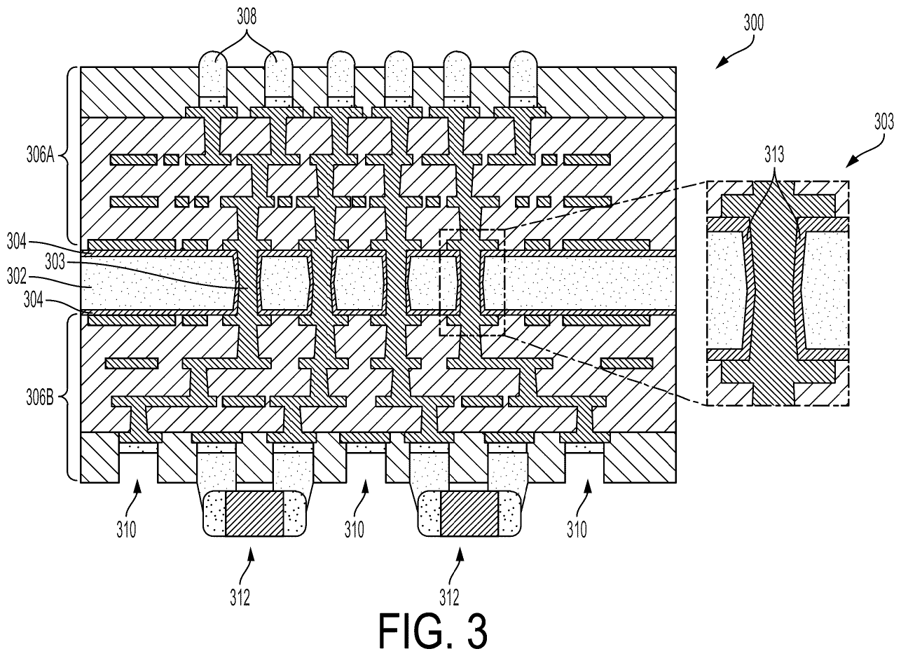

FIG. 3 illustrates an example package substrate 300 with a glass core 302 having dielectric buffer layer 304 in accordance with embodiments herein. In particular, the example package substrate 300 includes a glass core 302, which can help to provide rigidity to the package substrate 300 as described above. The dielectric buffer layer 304 is deposited on the top and bottom surfaces of the glass core 302, as well as on the sidewalls of the holes drilled in the glass core 302 to create TGVs 303 (e.g., on the sidewalls 313 as shown in the detailed view of a TGV 303). As shown, there is a lack of metallization or patterning directly in contact with the glass core 302. The dielectric buffer layer 304 may have a thickness of approximately 25-250 nm in some embodiments.

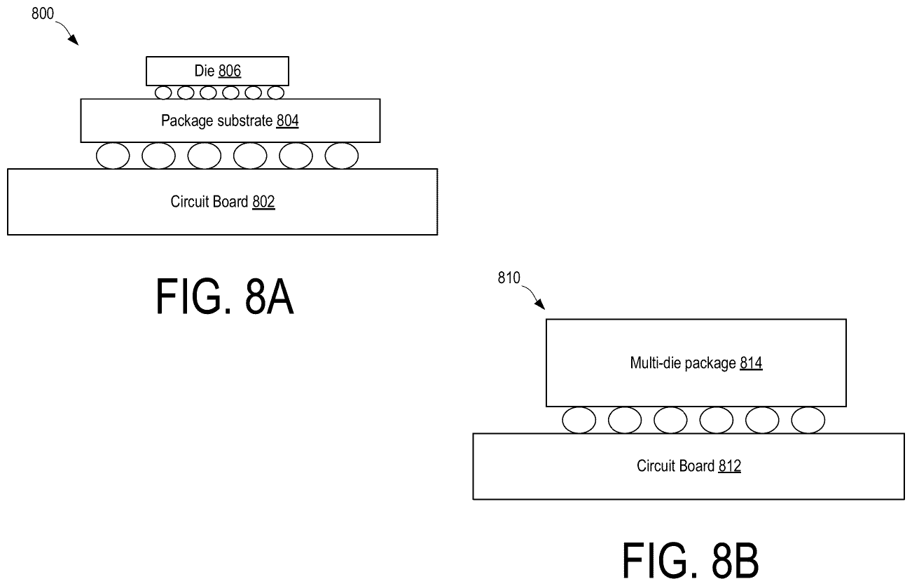

Buildup layers 306 are formed on the top and bottom sides of the glass core 302, with buildup layers 306A on the top side of the glass core 302 and the buildup layers 306B on bottom side of the glass core 302. The layers 306 include metal pillars, vias, and/or traces as shown to electrically couple the solder bumps 308 at the top of the package substrate 300 with the pads 310 at the bottom of the substrate. In certain instances, for example, an integrated circuit die may be coupled to a top side of the package substrate 300 and connect to the solder bumps 308, and the package substrate 300 may be coupled to a circuit board (e.g., a motherboard, main board, etc.) via the pads 310 at the bottom of the package substrate 300. For instance, the package substrate 300 may be incorporated into the system 800 of FIG. 8A as the package substrate 804. The package substrate 300 also includes land side capacitors 312 coupled on a bottom side of the package substrate 300.

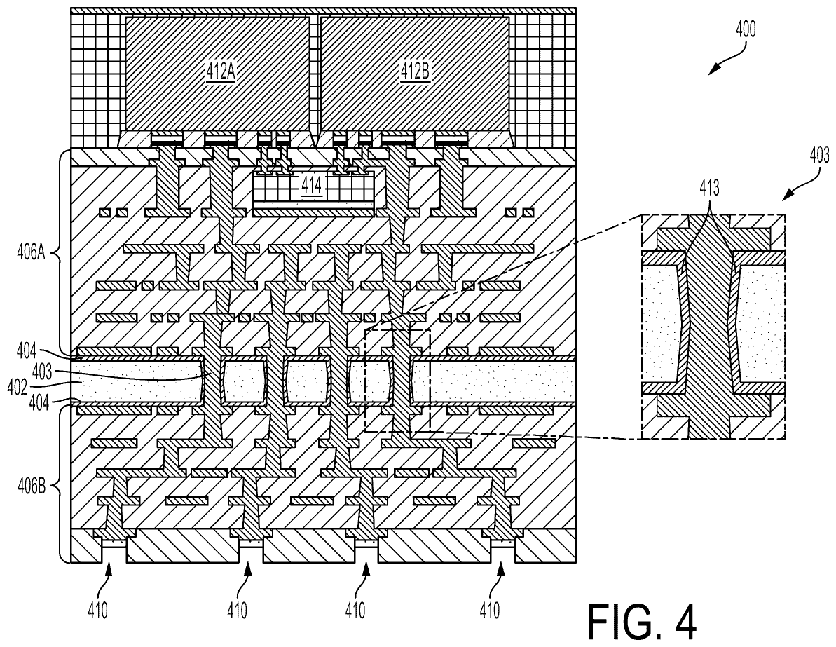

FIG. 4 illustrates an example multi-die package 400 with a glass core 402 having a dielectric buffer layer 404 in accordance with embodiments herein. As shown, the dielectric buffer layer 404 is deposited on the top and bottom surfaces of the glass core 402 as in the substrate 300 of FIG. 3, as well as on the sidewalls 413 of the holes drilled in the glass core 402 to create the TGVs 403. There are also buildup layers 406 formed on the top and bottom sides of the glass core 402, with buildup layers 406A formed on the top side of the glass core 402 and the buildup layers 406B formed on bottom side of the glass core 402. The layers 406 include metal pillars, vias, and/or traces as shown to electrically couple the integrated circuit (IC) dies 412 at the top of the multi-die package 400 with the pads 410 at the bottom of the package 400. In addition, there is a bridge component 414 located in the buildup layers 406A that electrically couples the first IC die 412A with the second IC die 412B. The bridge component 414 may include passive and/or active components to interconnect the IC dies 412. The bridge component 414 may be an Intel® embedded multi-die interconnect bridge (EMIB) in certain embodiments. In certain instances, the multi-die package 400 may be coupled to a circuit board (e.g., a motherboard, main board, etc.) via the pads 410 at the bottom of the package 400. For instance, the package 400 may be incorporated into the system 810 of FIG. 8B as the multi-die package 814.

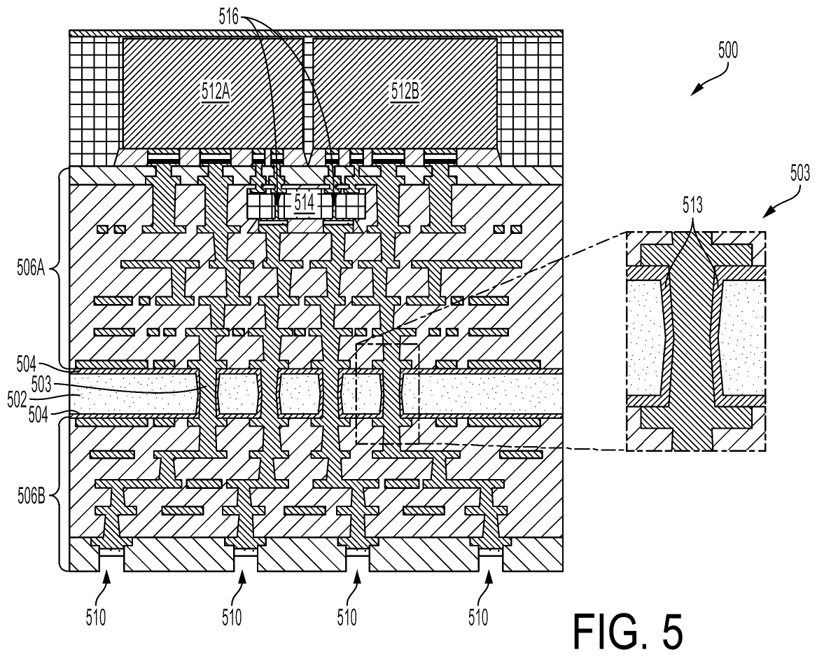

FIG. 5 illustrates another example multi-die package 500 with a glass core 502 having a dielectric buffer layer 504 in accordance with embodiments herein. In the example shown, the dielectric buffer layer 504 is deposited on the top and bottom surfaces of the glass core 502 as in the substrate 300 of FIG. 3, as well as on the sidewalls 513 of the holes drilled in the glass core 502 to create the TGVs 503. There are also buildup layers 506 formed on the top and bottom sides of the glass core 502, with buildup layers 506A formed on the top side of the glass core 502 and the buildup layers 506B formed on bottom side of the glass core 502. The layers 506 include metal pillars, vias, and/or traces as shown to electrically couple the integrated circuit (IC) dies 512 at the top of the multi-die package 500 with the pads 510 at the bottom of the package 500. The multi-die package 500 also includes a bridge component 514 similar to the bridge component 414 of the multi-die package 400; however, the bridge component 514 includes vias 516 from a top surface of the bridge 514 to the bottom surface of the bridge 514. The vias 516 may connect the IC dies 512 to certain traces, pillars, etc. within the buildup layers 506A. The bridge component 514 may be an Intel® embedded multi-die interconnect bridge (EMIB) in certain embodiments. In certain instances, the multi-die package 500 may be coupled to a circuit board (e.g., a motherboard, main board, etc.) via the pads 510 at the bottom of the package 500. For instance, the package 500 may be incorporated into the system 810 of FIG. 8B as the multi-die package 814.

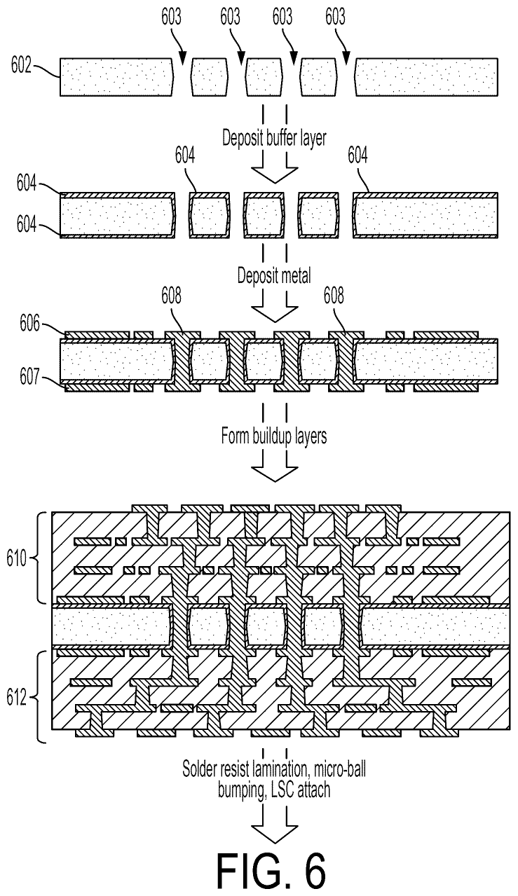

FIG. 6 illustrates an example process for manufacturing the package substrate of FIG. 3. The example process shown may include additional, fewer, or different operations than those shown or described below. In some embodiments, one or more of the operations shown in FIG. 6 include multiple operations, sub-operations, etc. The illustrations of FIG. 6 may thus represent different stages in the manufacturing process.

The example process begins with the drilling of holes 603 within a glass core 602. The holes 603 may be drilled using a laser sensitizing etch technique to form a connection from the top (FLI) side of the core 602 to the bottom (SLI) side of the core 603. Next, a dielectric buffer layer 604 is formed on the glass core 602 such that the dielectric buffer layer 604 is on the top and bottom sides of the core 602 as well as on the sidewalls of the holes 603. The buffer layer 604 may be formed using any suitable technique, such as, for example, Physical Vapor Deposition (PVD), Chemical Vapor Deposition (CVD), Atomic Layer Deposition (ALD). The dielectric buffer layer may include a dielectric material such as a silicon nitride (SiNx) material, a silicon oxynitride (SiOxNy) material, a silicon carbide (SiC) material, or another suitable dielectric material. For instance, in embodiments where layer 604 is a silicon nitride or a silicon oxynitride material, layer 604 includes both silicon and nitrogen in other than trace amounts. For example, in various embodiments where layer 604 is a silicon nitride or a silicon oxynitride material, layer 604 has more than 5% nitrogen, more than 10% nitrogen, more than 15% nitrogen, more than 20% nitrogen, more than 25% nitrogen, more than 30% nitrogen, or more than 35% nitrogen. Further, in various embodiments where layer 604 is a silicon nitride or a silicon oxynitride material, layer 604 has more nitrogen than glass core 602. Likewise, in embodiments where layer 604 is a silicon carbide material, layer 604 includes both silicon and carbon in other than trace amounts. For example, in various embodiments where layer 604 is a silicon carbide material, layer 604 has more than 5% carbon, more than 10% carbon, more than 15% carbon, more than 20% carbon, more than 25% carbon, more than 30% carbon, or more than 35% carbon. Further, in various embodiments where layer 604 is a silicon carbide material, layer 604 has more carbon than glass core 602.

The buffer layer can serve one or more purposes. For instance, the buffer layer 604 may act as an adhesion promoter, a diffusion barrier to copper that is subsequently deposited, and/or as a buffer layer that manages the stress between the copper and the underlying glass core. The deposition of the buffer layer 604 may be done at high temperatures, e.g., >200 C, such as at ˜400 C, which may allow for a high quality (e.g., dense) nitride layer to be formed.

Next, metal (e.g., copper or a copper alloy) is plated to create pads and traces 606 on the top and bottom sides of the core 602 and is formed within the holes 603 to create TGVs 608. The TGVs may be formed using any suitable through hole plating approach. In some embodiments, the filling of the holes may be done such that the metal is over plated and then planarized onto the surface of the buffer layer 604 on the top/bottom surface of the core 602. A standard lithography process can then be used to pattern the pads and traces 606 on the buffer layer 604. The presence of the buffer layer 604 can enable desired routing including copper planes which otherwise would not have been possible due to the stress issues between copper and glass described above. In addition, the Imax and TGV reliability concerns may be overcome with this approach as there are no extra drilling steps involved in the making of the TGVs to connect the patterning and subsequent RDLs as in other approaches. In other embodiments, instead of planarizing the metal onto the buffer layer surface, a wet or dry semi-additive process (SAP) or similar process can be used to form the patterning of the pads and traces 606. Such a process might call for the fill of the TGVs 608 and the formation of pads and traces 606 on the buffer layer surface at the same time. Next, a two-sided wet/dry SAP process can be performed to create a desired number of layers within the buildup layers 610, 612. The buildup layers may include a number of metallization layers (which may also be referred to as routing or redistribution layers (RDLs)) connected by metal pillars (e.g., layers 611A and 611B connected by pillar 613). This may include Ajinomoto build-up film (ABF) lamination, via drilling, seed layer deposition, lithography patterning for the plating and resist and seed strip all the way up to the solder resist surface layer. This can then be followed by traditional solder resist lamination, surface finish, micro-ball bumping, and LSC attachment, etc. to yield a package substrate similar to the one shown in FIG. 3 and described above.

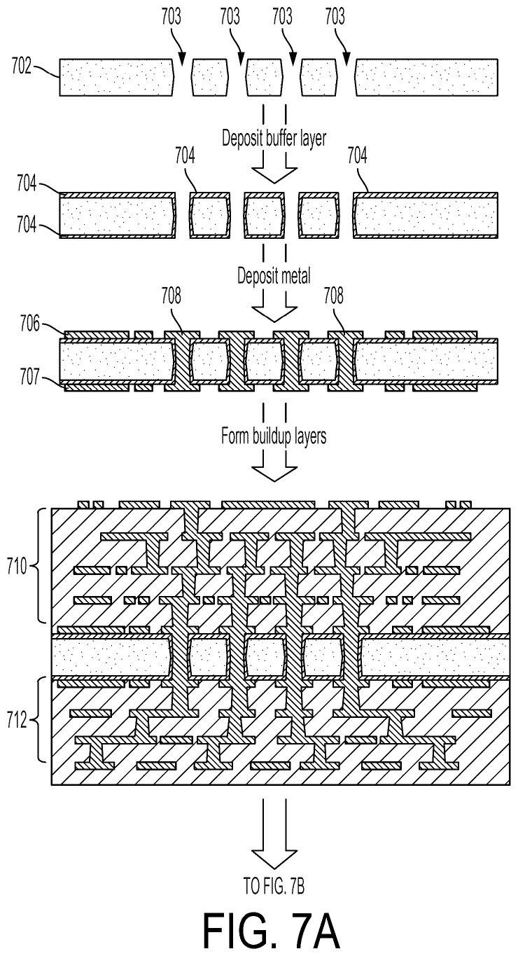

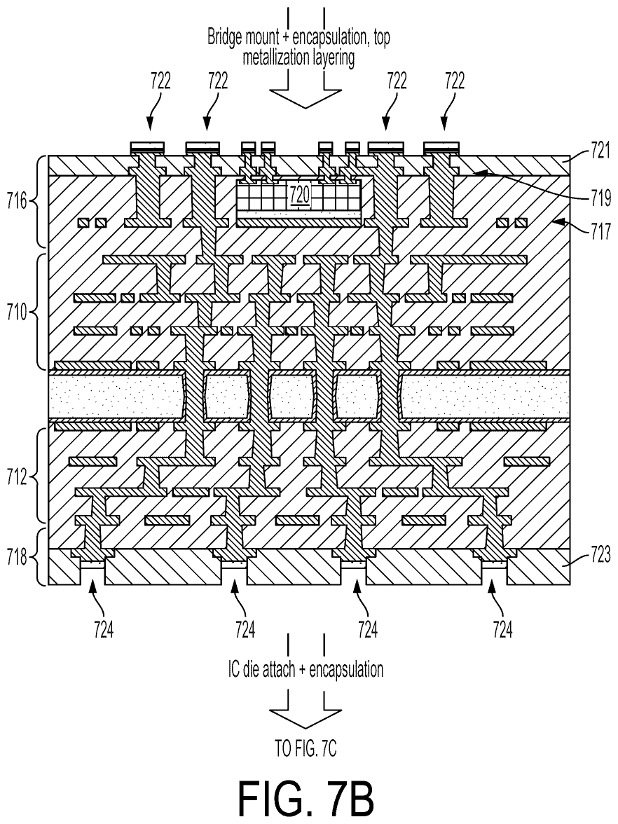

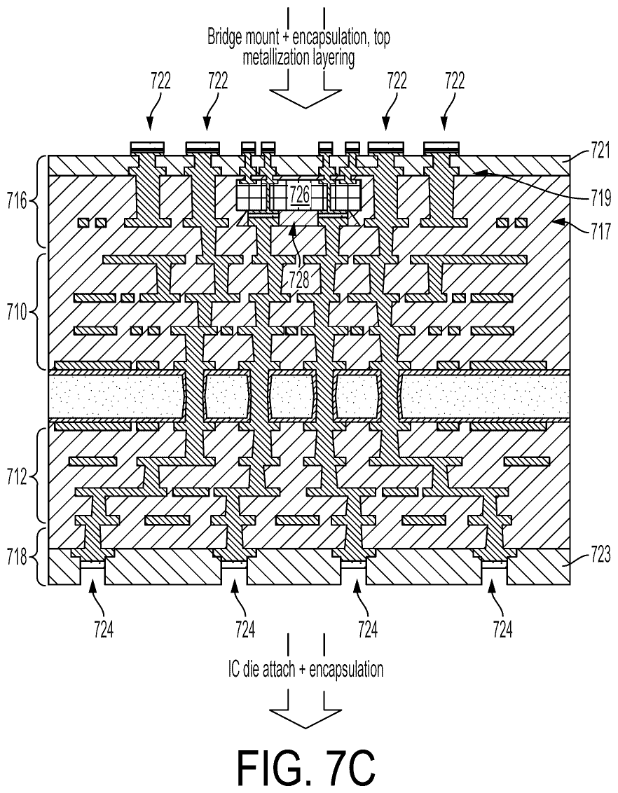

FIGS. 7A-7C illustrate example processes for manufacturing the multi-die packages of FIGS. 4-5. The example process shown may include additional, fewer, or different operations than those shown or described below. In some embodiments, one or more of the operations shown in FIGS. 7A-7C include multiple operations, sub-operations, etc. The illustrations of FIGS. 7A-7C may thus represent different stages in the manufacturing process(es).

The example process of FIG. 7A begins with the drilling of holes 703 within a glass core 702. The holes 703 may be drilled using a laser sensitizing etch technique to form a connection from the top (FLI) side of the core 702 to the bottom (SLI) side of the core 703. Next, a dielectric buffer layer 704 is formed on the glass core 702 such that the dielectric buffer layer 704 is on the top and bottom sides of the core 702 as well as on the sidewalls of the holes 703. The buffer layer 704 may be formed using any suitable technique, such as, for example, Physical Vapor Deposition (PVD), Chemical Vapor Deposition (CVD), Atomic Layer Deposition (ALD). The dielectric buffer layer may include a silicon nitride (SiNx) material, a silicon oxynitride (SiOxNy) material, a silicon carbide (SiC) material, or another suitable material. The buffer layer can serve one or more purposes. For instance, the buffer layer 704 may act as an adhesion promoter, a diffusion barrier to copper that is subsequently deposited, and/or as a buffer layer that manages the stress between the copper and the underlying glass core. The deposition of the buffer layer 704 may be done at high temperatures, e.g., >200 C, such as at ˜400 C, which may allow for a high quality (e.g., dense) nitride layer to be formed.

Next, metal (e.g., copper or a copper alloy) is plated to create pads and traces 706 on the top and bottom sides of the core 702 and is formed within the holes 703 to create TGVs 708. The TGVs may be formed using any suitable through hole plating approach. In some embodiments, the filling of the holes may be done such that the metal is over plated and then planarized onto the surface of the buffer layer 704 on the top/bottom surface of the core 702. A standard lithography process can then be used to pattern the pads and traces 706 on the buffer layer 704. The presence of the buffer layer 704 can enable desired routing including copper planes which otherwise would not have been possible due to the stress issues between copper and glass described above. In addition, the Imax and TGV reliability concerns may be overcome with this approach as there are no extra drilling steps involved in the making of the TGVs to connect the patterning and subsequent RDLs as in other approaches. In other embodiments, instead of planarizing the metal onto the buffer layer surface, a wet or dry semi-additive process (SAP) or similar process can be used to form the patterning of the pads and traces 706. Such a process might call for the fill of the TGVs 708 and the formation of pads and traces 706 on the buffer layer surface at the same time. Next, a two-sided wet/dry SAP process can be performed to create a desired number of RDLs within the buildup layers 710, 712. This may include ABF lamination, via drilling, seed layer deposition, lithography patterning for the plating and resist and seed strip all the way up to the solder resist surface layer.

The apparatus can then have a bridge component (e.g., 414, 514) and/or IC dies (e.g., 412, 512) attached thereto, e.g., as shown in FIGS. 7B and 7C. For instance, additional buildup layers 716 can be formed on the buildup layers 710, with the buildup layers 716 including a non-TSV bridge component 720 as shown in FIG. 7B or a TSV bridge component 726 as shown in FIG. 7C. The formation of the buildup layers 716 may include the formation of an additional metallization layer 717, mounting of the bridge component 720 or 726 on the metallization layer 717, encapsulation of the bridge component 720, formation of metallization layer 719 above the bridge component 720, formation of the solder resist layer 721, and then formation of contact pads 722 on the solder resist layer 721. Additionally, buildup layers 718 may be formed on the buildup layers 712. The buildup layers 718 may include a solder resist layer 723 formed around electrical contact pads 724. In the example shown in FIG. 7B, the bridge component 720 may be a passive bridge that is bonded to a plane of copper created between copper pillars as shown. In the example shown in FIG. 7C, the bridge component 726 may be solder attached to the metallization layer 717 and then an underfill 728 can be deposited in the space around the solder attachment. The bridge component 720, 726 and surrounding copper pillars are then encapsulated with a dielectric (e.g., ABF) and polished/grinded back to expose the copper pillar and the bridge die pads/pillars. The subsequent encapsulation layer metallization (719), solder resist lithography loop (721), and selective surface finishing (SSF), and pad formation (722) can then be performed. Thereafter, IC dies can be attached to the top of the apparatus and encapsulated to yield a package similar to those shown in FIG. 4 or 5 and described above.

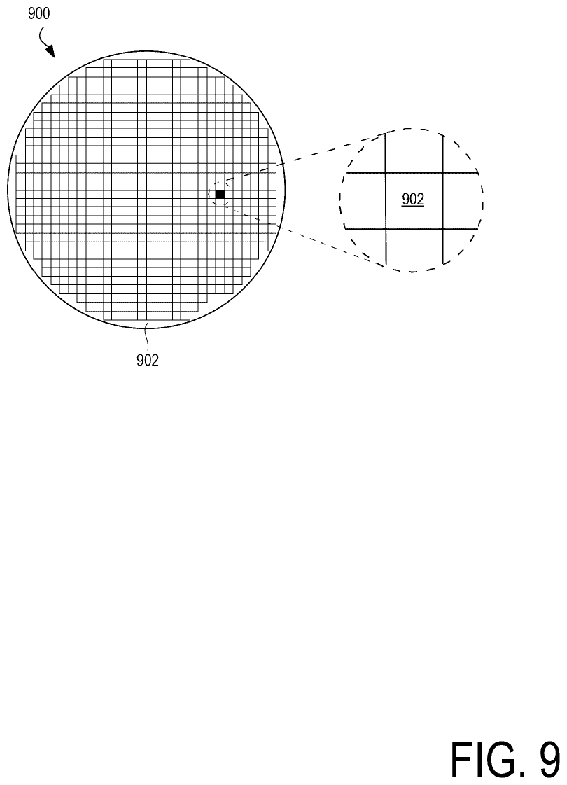

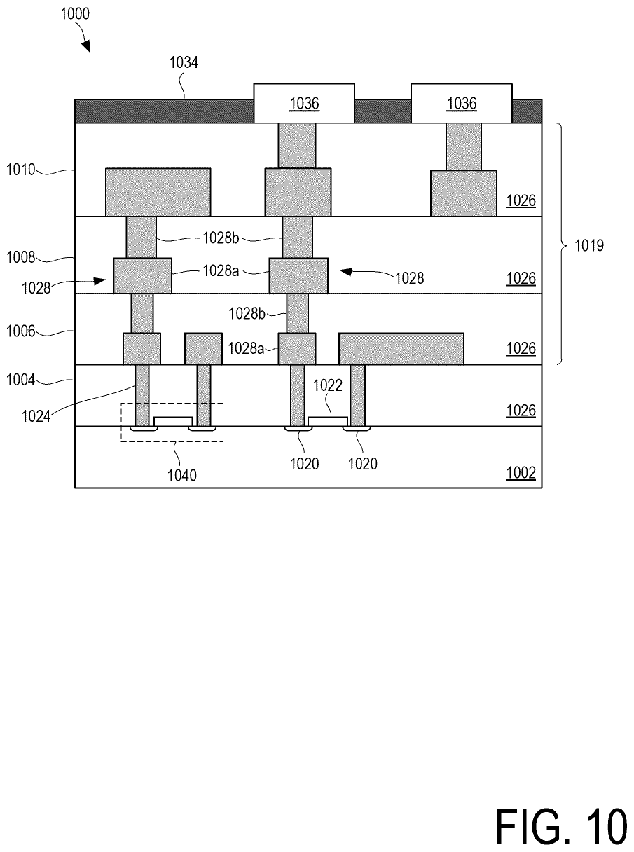

FIGS. 8A-8B illustrate example systems 800, 810 that may incorporate the glass core architectures described herein. The example system 800 of FIG. 8A includes a circuit board 802, which may be implemented as a motherboard or main board of a computer system in some embodiments. The example system 800 also includes a package substrate 804 with an integrated circuit die 806 attached to the package substrate 804. The die 806 may be a packaged or unpacked integrated circuit product that includes one or more integrated circuit dies (e.g., the die 902 of FIG. 9, the integrated circuit device 1000 of FIG. 10) and/or one or more other suitable components. The die 806 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die 806 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die 806 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. The package substrate 804 may provide electrical connections between the die 806 and the circuit board 802.

Similar to the system 800, the system 810 also includes a circuit board 812, which may be implemented as a motherboard or main board of a computer system in some embodiments. The system 810 also includes a multi-die package 814, which includes multiple integrated circuits/dies (e.g., 806), and interconnections between the dies in one or more metallization layers. The multi-die package 814 may include, for example, one or more silicon interposers, one or more silicon bridges embedded in the package substrate (e.g., an Intel® embedded multi-die interconnect bridge (EMIB)), or combinations thereof.

The main circuit boards 810, 812 may provide electrical connections to other components of a computer system, e.g., memory, storage, network interfaces, peripheral devices, power supplies, etc. The main circuit board may include one or more traces and circuit components to provide interconnects between such computer system components.

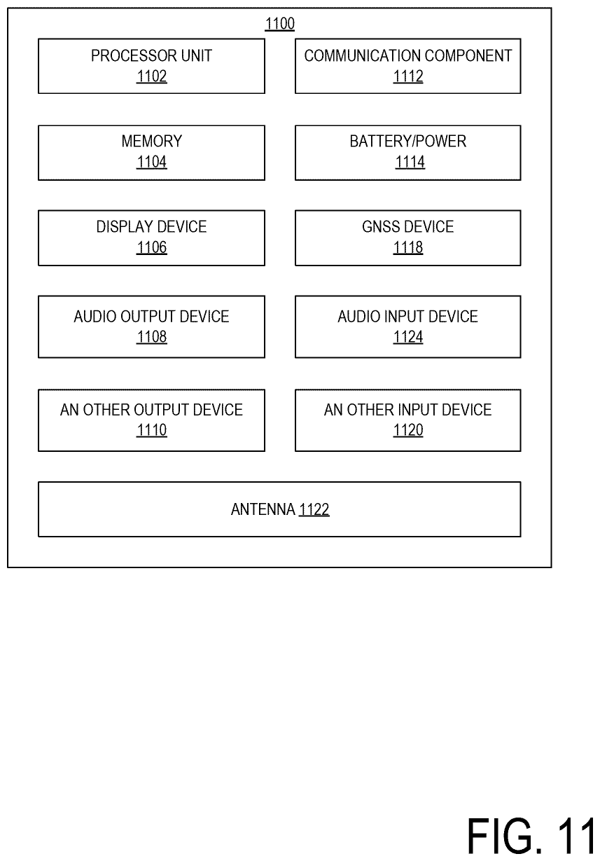

FIG. 9 is a top view of a wafer 900 and dies 902 that may be implemented in or along with any of the embodiments disclosed herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1102 of FIG. 11) or other logic that is configured to store information in the memory devices or execute instructions stored in the memory array.

FIG. 10 is a cross-sectional side view of an integrated circuit device 1000 that may be included in any of the embodiments disclosed herein. One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page from the perspective of FIG. 10. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board or a package substrate, e.g., 112). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 11 is a block diagram of an example electrical device 1100 that may include one or more of the embodiments disclosed herein. For example, any suitable ones of the components of the electrical device 1100 may include one or more of assemblies 100, integrated circuit devices 1000, or integrated circuit dies 902 disclosed herein. A number of components are illustrated in FIG. 11 as included in the electrical device 1100, but any one or more of these components may be omitted or duplicated, as suitable for the application. In some embodiments, some or all of the components included in the electrical device 1100 may be attached to one or more motherboards mainboards, or system boards. In some embodiments, one or more of these components are fabricated onto a single system-on-a-chip (SoC) die.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1100 can comprise one or more processor units 1102 that are heterogeneous or asymmetric to another processor unit 1102 in the electrical device 1100. There can be a variety of differences between the processing units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include another output device 1110 (or corresponding interface circuitry, as discussed above). Examples of the other output device 1110 may include an audio codec, a video codec, a printer, a wired or wireless transmitter for providing information to other devices, or an additional storage device.

The electrical device 1100 may include another input device 1120 (or corresponding interface circuitry, as discussed above). Examples of the other input device 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an integrated circuit apparatus comprising: a glass core layer; a plurality of through-glass vias (TGVs) comprising conductive metal and extending from a first side of the glass core layer to a second side of the glass core layer opposite the first side; dielectric material between the TGVs and the glass core layer; a buildup layer on the first side of the glass core layer, the buildup layer comprising: a plurality of metallization layers connected by metal pillars, at least one metallization layer of the buildup layer coupled to the TGVs; and an encapsulated bridge comprising circuitry to interconnect multiple integrated circuit dies. The dielectric layer may include nitrogen or carbon, and in some Examples, may comprise more nitrogen or carbon than the glass core layer.

Example 2 includes the subject matter of Example 1, further comprising: a first integrated circuit die coupled to the encapsulated bridge; and a second integrated circuit die coupled to the encapsulated bridge.

Example 3 includes the subject matter of Example 1 or 2, wherein the encapsulated bridge comprises passive and active circuitry.

Example 4 includes the subject matter of any one of Examples 1-3, wherein the encapsulated bridge comprises metal vias extending from a first side of the bridge to a second side of the bridge opposite the first side.

Example 5 includes the subject matter of any one of Examples 1-4, wherein the buildup layer is a first buildup layer and the apparatus further comprises a second buildup layer on a second side of the glass core layer, the second buildup layer comprising a plurality of metallization layers connected by metal pillars, at least one metallization layer of the second buildup layer coupled to the TGVs.

Example 6 includes the subject matter of any one of Examples 1-5, wherein the dielectric material includes one or more of silicon nitride, silicon oxynitride, and silicon carbide.

Example 7 includes the subject matter of any one of Examples 1-6, wherein the dielectric material has a thickness between 25-250 nm.

Example 8 includes the subject matter of any one of Examples 1-7, wherein the dielectric material completely covers a surface of the first side of the glass core layer and a surface of the second side of the glass core layer.

Example 9 includes the subject matter of any one of Examples 1-8, wherein there is no metal in contact with the glass core layer.

Example 10 includes the subject matter of any one of Examples 1-9, wherein the conductive metal is copper or a copper alloy.

Example 11 is a system comprising: a multi-die integrated device comprising: a glass core layer; a plurality of through-glass vias (TGVs) comprising conductive metal and extending from a first side of the glass core layer to a second side of the glass core layer opposite the first side; dielectric material between the TGVs and the glass core layer; a buildup layer on the first side of the glass core layer, the buildup layer comprising a plurality of metallization layers connected by metal pillars, at least one metallization layer of the buildup layer coupled to the TGVs, and an encapsulated bridge comprising circuitry to interconnect multiple integrated circuit dies; a plurality of integrated circuit dies on a side of the buildup layer opposite the glass core layer, the integrated circuit dies coupled to the encapsulated bridge. The dielectric layer may include nitrogen or carbon, and in some Examples, may comprise more nitrogen or carbon than the glass core layer.

Example 12 includes the subject matter of Example 11, wherein the encapsulated bridge comprises passive and active circuitry.

Example 13 includes the subject matter of any one of Examples 11-12, wherein the encapsulated bridge comprises metal vias extending from a first side of the bridge to a second side of the bridge opposite the first side.

Example 14 includes the subject matter of any one of Examples 11-13, wherein the buildup layer is a first buildup layer and the apparatus further comprises a second buildup layer on a second side of the glass core layer, the second buildup layer comprising a plurality of metallization layers connected by metal pillars, at least one metallization layer of the second buildup layer coupled to the TGVs.

Example 15 includes the subject matter of any one of Examples 11-14, wherein the dielectric material includes one or more of silicon nitride, silicon oxynitride, and silicon carbide.

Example 16 includes the subject matter of any one of Examples 11-15, wherein the dielectric material completely covers a surface of the first side of the glass core layer and a surface of the second side of the glass core layer.

Example 17 includes the subject matter of any one of Examples 11-16, wherein there is no metal in contact with the glass core layer.

Example 18 includes the subject matter of any one of Examples 11-17, wherein the conductive metal is copper or a copper alloy.

Example 19 includes the subject matter of any one of Examples 11-18, further comprising a main circuit board coupled to the multi-die integrated circuit package.

Example 20 is method of forming an integrated circuit apparatus, comprising: forming holes in a glass layer, the holes extending from a first side of the glass layer to a second side of the glass layer; depositing a dielectric material on the first side of the glass layer, the second side of the glass layer, and on the surfaces inside the holes; forming a plurality of through-glass vias (TGVs) comprising conductive metal, the TGVs electrically coupling the first side of the glass layer to the second side of the glass layer; forming a buildup layer on the first side of the glass layer, the buildup layer comprising a plurality of metallization layers connected by metal pillars, at least one metallization layer of the buildup layer coupled to the TGVs; and coupling a bridge device to the buildup layer, the bride device comprising circuitry to interconnect a plurality of integrated circuit dies. The dielectric layer may include nitrogen or carbon, and in some Examples, may comprise more nitrogen or carbon than the glass core layer.

Example 21 includes the subject matter of Example 20, wherein coupling the bridge device to the buildup layer comprises mounting the bridge device to a copper layer in the buildup layer.

Example 22 includes the subject matter of Example 20, wherein coupling the bridge device to the buildup layer comprises soldering the bridge device to a metallization layer in the buildup layer and underfilling an area between the bridge device and the metallization layer.

Example 23 includes the subject matter of any one of Examples 20-23, further comprising encapsulating the bridge device and forming metal pillars around the bridge device.

Example 24 includes the subject matter of any one of Examples 20-23, further comprising coupling a plurality of integrated circuit dies to the bridge device.

Example 25 includes the subject matter of any one of Examples 20-24, wherein the buildup layer is a first buildup layer and the method further comprises forming a second buildup layer on the second side of the glass layer, the second buildup layer comprising a plurality of metallization layers connected by metal pillars, at least one metallization layer of the second buildup layer coupled to the TGVs.

Example 26 is a product formed by the process of any one of Examples 20-25.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An integrated circuit apparatus comprising:
a glass core layer;
a plurality of through-glass vias (TGVs) comprising conductive metal and extending from a first side of the glass core layer to a second side of the glass core layer opposite the first side;
dielectric material between the TGVs and the glass core layer, wherein the dielectric material includes nitrogen or carbon;
a buildup layer on the first side of the glass core layer, the buildup layer comprising:
a plurality of metallization layers connected by metal pillars, at least one metallization layer of the buildup layer coupled to the TGVs; and
an encapsulated bridge comprising circuitry to interconnect multiple integrated circuit dies.

2. The apparatus of claim 1, further comprising:
a first integrated circuit die coupled to the encapsulated bridge; and
a second integrated circuit die coupled to the encapsulated bridge.

3. The apparatus of claim 1, wherein the encapsulated bridge comprises passive and active circuitry.

4. The apparatus of claim 1, wherein the encapsulated bridge comprises metal vias extending from a first side of the bridge to a second side of the bridge opposite the first side.

5. The apparatus of claim 1, wherein the buildup layer is a first buildup layer and the apparatus further comprises a second buildup layer on a second side of the glass core layer, the second buildup layer comprising a plurality of metallization layers connected by metal pillars, at least one metallization layer of the second buildup layer coupled to the TGVs.

6. The apparatus of claim 1, wherein the dielectric material includes one or more of silicon nitride, silicon oxynitride, and silicon carbide.

7. The apparatus of claim 1, wherein the dielectric material has a thickness between 25-250 nm.

8. The apparatus of claim 1, wherein the dielectric material completely covers a surface of the first side of the glass core layer and a surface of the second side of the glass core layer.

9. The apparatus of claim 1, wherein there is no metal in contact with the glass core layer.

10. The apparatus of claim 1, wherein the dielectric layer comprises more nitrogen or carbon than the glass core layer.

11. A system comprising:
a multi-die integrated device comprising:
a glass core layer;
a plurality of through-glass vias (TGVs) comprising conductive metal and extending from a first side of the glass core layer to a second side of the glass core layer opposite the first side;
dielectric material between the TGVs and the glass core layer, wherein the dielectric material includes nitrogen or carbon;
a buildup layer on the first side of the glass core layer, the buildup layer comprising a plurality of metallization layers connected by metal pillars, at least one metallization layer of the buildup layer coupled to the TGVs, and an encapsulated bridge comprising circuitry to interconnect multiple integrated circuit dies;
a plurality of integrated circuit dies on a side of the buildup layer opposite the glass core layer, the integrated circuit dies coupled to the encapsulated bridge.

12. The system of claim 11, wherein the encapsulated bridge comprises passive and active circuitry.

13. The system of claim 11, wherein the encapsulated bridge comprises metal vias extending from a first side of the bridge to a second side of the bridge opposite the first side.

14. The system of claim 11, wherein the buildup layer is a first buildup layer and the apparatus further comprises a second buildup layer on a second side of the glass core layer, the second buildup layer comprising a plurality of metallization layers connected by metal pillars, at least one metallization layer of the second buildup layer coupled to the TGVs.

15. The system of claim 11, wherein the dielectric material includes one or more of silicon nitride, silicon oxynitride, and silicon carbide.

16. The system of claim 11, wherein the dielectric material completely covers a surface of the first side of the glass core layer and a surface of the second side of the glass core layer.

17. The system of claim 11, wherein there is no metal in contact with the glass core layer.

18. The system of claim 11, wherein the dielectric layer comprises more nitrogen or carbon than the glass core layer.

19. The system of claim 11, further comprising a main circuit board coupled to the multi-die integrated circuit package.

20. A method comprising:
forming holes in a glass layer, the holes extending from a first side of the glass layer to a second side of the glass layer;
depositing a dielectric material on the first side of the glass layer, the second side of the glass layer, and on the surfaces inside the holes, wherein the dielectric material includes nitrogen or carbon;
forming a plurality of through-glass vias (TGVs) comprising conductive metal, the TGVs electrically coupling the first side of the glass layer to the second side of the glass layer;
forming a buildup layer on the first side of the glass layer, the buildup layer comprising a plurality of metallization layers connected by metal pillars, at least one metallization layer of the buildup layer coupled to the TGVs; and
coupling a bridge device to the buildup layer, the bride device comprising circuitry to interconnect a plurality of integrated circuit dies.

21. The method of claim 20, wherein coupling the bridge device to the buildup layer comprises mounting the bridge device to a copper layer in the buildup layer.

22. The method of claim 20, wherein coupling the bridge device to the buildup layer comprises soldering the bridge device to a metallization layer in the buildup layer and underfilling an area between the bridge device and the metallization layer.

23. The method of claim 20, further comprising encapsulating the bridge device and forming metal pillars around the bridge device.

24. The method of claim 20, further comprising coupling a plurality of integrated circuit dies to the bridge device.

25. The method of claim 20, wherein the buildup layer is a first buildup layer and the method further comprises forming a second buildup layer on the second side of the glass layer, the second buildup layer comprising a plurality of metallization layers connected by metal pillars, at least one metallization layer of the second buildup layer coupled to the TGVs.
